(19) United States
(12) Patent Application Publication
(10) Pub. No.: US 2024/0272215 A1
(43) Pub. Date: Aug. 15, 2024

(54) ELECTROMAGNETIC WAVE CALCULATION SYSTEM AND METHOD OF OBTAINING PREVIOUS DATA

(71) Applicant: Mitsubishi Electric Corporation, Tokyo (JP)

(72) Inventors: Toshiya TADAKUMA, Tokyo (JP); Kazuki TAKAKURA, Tokyo (JP); Shinobu NAGASAWA, Tokyo (JP); Nobuyuki HARUNA, Tokyo (JP)

(73) Assignee: Mitsubishi Electric Corporation, Tokyo (JP)

(21) Appl. No.: 18/539,490

(22) Filed: Dec. 14, 2023

(30) Foreign Application Priority Data
Feb. 14, 2023 (JP) 2023-020404

(51) Int. Cl. G01R 29/08; G01R 31/34

(52) U.S. Cl. CPC G01R 29/0892; G01R 29/0878; G01R 31/343

(57) ABSTRACT

An electromagnetic wave calculation system according to the present disclosure is an electromagnetic wave calculation system calculating an electromagnetic wave generated in a semiconductor device, including: an electromagnetic wave simulator and a previous data recording part, wherein the electromagnetic wave simulator and the previous data recording part have communication with each other via network, the previous data recording part records electromagnetic wave data of the semiconductor device corresponding to a type name of the semiconductor and a usage condition of the semiconductor device as previous data, and when the type name and the usage condition of the semiconductor device are inputted, the electromagnetic wave simulator has communication with the previous data recording part, and outputs the electromagnetic wave data under the usage condition of the semiconductor device.

### FIELD OF THE INVENTION

The present disclosure relates an electromagnetic wave calculation system calculating strength of an electromagnetic wave emitted from a semiconductor device, and particularly relates to an electromagnetic wave calculation system simulating strength of an electromagnetic wave emitted from a semiconductor device in driving a motor.

### DESCRIPTION OF THE BACKGROUND ART

Conventionally, in confirming an electromagnetic wave generated in an operation of a semiconductor device, a user of the semiconductor device can confirm the electromagnetic wave generated in the semiconductor device only when the user actually drives the semiconductor device.

For example, Japanese Patent Application Laid-Open No. 2020-109376 discloses that a semiconductor device is switching-operated in accordance with an electrical signal, and an electromagnetic noise is generated in accordance with the switching operation to confirm an electromagnetic wave.

### SUMMARY

As described above, there is a problem that in confirming the electromagnetic wave generated in the operation of the semiconductor device, the user can confirm the electromagnetic wave only when the user obtains and drives the semiconductor device, and it takes time to select the semiconductor device to be used.

An object of the present disclosure is to provide an electromagnetic wave calculation system in which a user can confirm an electromagnetic wave generated in an operation of a semiconductor device without using the semiconductor device.

An electromagnetic wave calculation system according to the present disclosure is an electromagnetic wave calculation system calculating an electromagnetic wave generated in a semiconductor device, including: an electromagnetic wave simulator and a previous data memory, wherein the electromagnetic wave simulator and the previous data memory have communication with each other via network, the previous data memory records electromagnetic wave data of the semiconductor device corresponding to a type name of the semiconductor and a usage condition of the semiconductor device as previous data, and when the type name and the usage condition of the semiconductor device are inputted, the electromagnetic wave simulator has communication with the previous data memory, and outputs the electromagnetic wave data under the usage condition of the semiconductor device.

According to the electromagnetic wave calculation system according to the present disclosure, when the type name and the usage condition of the semiconductor device are inputted, the electromagnetic wave simulator has communication with the previous data memory, and outputs the electromagnetic wave data under the usage condition of the semiconductor device, thus the electromagnetic wave generated in the operation of the semiconductor device can be confirmed without using the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a functional block diagram illustrating a configuration of an electromagnetic wave calculation system according to an embodiment 1 of the present disclosure.

FIG. 2 is a diagram illustrating an outline of a system calculating an electromagnetic wave.

FIG. 3 is a diagram illustrating a circuit in which a dielectric load is connected to an output of a single-phase full bridge circuit as an example of a measured object.

FIG. 4 is a timing chart illustrating a voltage signal from an antenna obtained by applying a pulse signal in a double pulse test.

FIG. 5 is a diagram illustrating a profile of electromagnetic wave strength obtained by performing Fourier transformation on the voltage signal.

FIG. 6 is a diagram explaining a concept of superposition of the profile.

FIG. 7 is a diagram explaining a concept of superposition of the profile.

FIG. 8 is a diagram explaining a concept of superposition of the profile.

FIG. 9 is a diagram illustrating a profile in a case of changing current flowing in a dielectric load of a measured object.

FIG. 10 is a diagram illustrating a circuit in which a dielectric load is connected to an output of a single-phase full bridge circuit as an example of a measured object.

FIG. 11 is a timing chart illustrating a voltage signal from an antenna obtained by applying a pulse signal in a double pulse test.

FIG. 12 is a diagram explaining a bus wiring in a single-phase full bridge circuit of a measured object.

FIG. 13 is a diagram in which a capacitor having a fixed capacity is connected to a single-phase full bridge circuit of a measured object.

FIG. 14 is a diagram illustrating a circuit in which a dielectric load is connected to an output of a half bridge circuit as an example of a measured object.

FIG. 15 is a diagram illustrating a circuit in which a dielectric load is connected to an output of a half bridge circuit as an example of a measured object.

FIG. 16 is a diagram illustrating a circuit in which a dielectric load is connected to an output of a half bridge circuit as an example of a measured object.

FIG. 17 is a diagram illustrating a flow of current when a three-phase full bridge circuit is operated.

FIG. 18 is a diagram illustrating a flow of current when a three-phase full bridge circuit is operated.

FIG. 19 is a timing chart explaining an electromagnetic wave generated at a time of turning on measured in a double pulse test.

FIG. 20 is a conceptual diagram explaining a method of obtaining a profile by a complement.

FIG. 21 is a conceptual diagram explaining a method of obtaining a profile by a complement.

FIG. 22 is a conceptual diagram explaining a method of obtaining a profile by a complement.

FIG. 23 is a conceptual diagram explaining a method of obtaining a profile by a complement.

FIG. 24 is a diagram explaining a complement by a linear approximation.

### DESCRIPTION OF THE PREFERRED EMBODIMENTS

### Embodiment 1

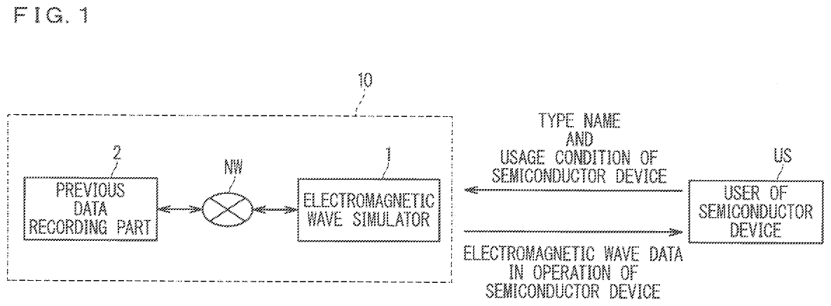

FIG. 1 is a functional block diagram illustrating a configuration of an electromagnetic wave calculation system 10 according to the present disclosure. As illustrated in FIG. 1, the electromagnetic wave calculation system 10 includes an electromagnetic wave simulator 1 and a previous data recording part 2, and the electromagnetic wave simulator 1 and the previous data recording part 2 perform data communication via network NW such as Internet, for example.

The previous data recording part 2 is provided in a server computer constituting a cloud environment, and data indicating a behavior in an operation is previously inputted for each type name of the semiconductor device.

The electromagnetic wave simulator 1 can be made using a computer connected to the network NW, and is achieved by the computer executing a program. That is to say, the electromagnetic wave simulator 1 is achieved by a processing circuit. A processor such as a central processing unit (CPU) or a digital signal processor (DSP) is applied to the processing circuit, and a function of the electromagnetic wave simulator 1 is achieved by executing the program stored in a storage device. The electromagnetic wave simulator 1 is made using the computer on the network NW, thus can be accessed from anywhere, and convenience is increased.

The electromagnetic wave simulator 1 is operated when a user US of a semiconductor device inputs a type name assigned by a manufacturing company manufacturing the semiconductor device and a usage condition of the semiconductor device, and has data communication with the previous data recording part 2, thereby outputting electromagnetic wave data in an operation of the semiconductor device having the inputted type name. The electromagnetic wave calculation system 10 notifies the user US of the semiconductor device of the outputted electromagnetic wave data. The user US of the semiconductor device can confirm the electromagnetic wave data of the semiconductor device without actually purchasing and operating the semiconductor device.

In this manner, the electromagnetic wave calculation system 10 is provided on the network. The user US of the semiconductor device can use the electromagnetic wave calculation system 10 in various forms. For example, when the electromagnetic wave calculation system 10 is provided as an office application such as Excel having a link to the electromagnetic wave calculation system 10, and when the type name and the usage condition of the semiconductor device are inputted to the office application, the user US can be linked to the electromagnetic wave calculation system 10 to obtain the electromagnetic wave data. It is also applicable that the electromagnetic wave calculation system 10 can be accessed from a homepage of a company of the user US of the semiconductor device to obtain the electromagnetic wave data using the electromagnetic wave calculation system 10 on the homepage. Thus, the electromagnetic wave calculation system 10 is convenient for the user US of the semiconductor device. Access to the electromagnetic wave calculation system 10 can be limited so that only the regular user US of the semiconductor device can use the electromagnetic wave calculation system 10. The regular user US of the semiconductor device indicates a company having business with a manufacturing company manufacturing the semiconductor device or a company scheduled to use a product of a manufacturing company manufacturing the semiconductor device in the future, for example.

A method of obtaining the previous data recorded in the previous data recording part 2 is described hereinafter. A procedure of obtaining the previous data is described firstly.

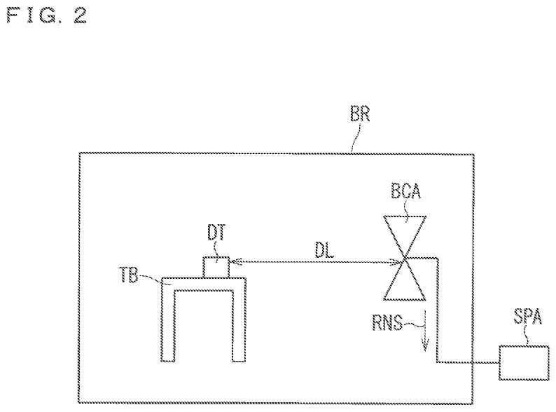

(1) FIG. 2 is a diagram illustrating an outline of a system measuring an electromagnetic wave. In a radio wave darkroom BR used for measuring the electromagnetic wave illustrated in FIG. 2, a measured object DT is provided on a non-conductive test bench TB having a height of 0.8 m in accordance with a standard 16 (CISPR 16) of International Special Committee on Radio Interference, for example.

(2) As illustrated in FIG. 2, a biconical antenna BCA, for example, is disposed with a distance DL of 3 m to 10 m from the measured object DT. A voltage signal RNS from the biconical antenna BCA is outputted to a spectrum analyzer SPA provided to an outer part of the radio wave darkroom BR and analyzed.

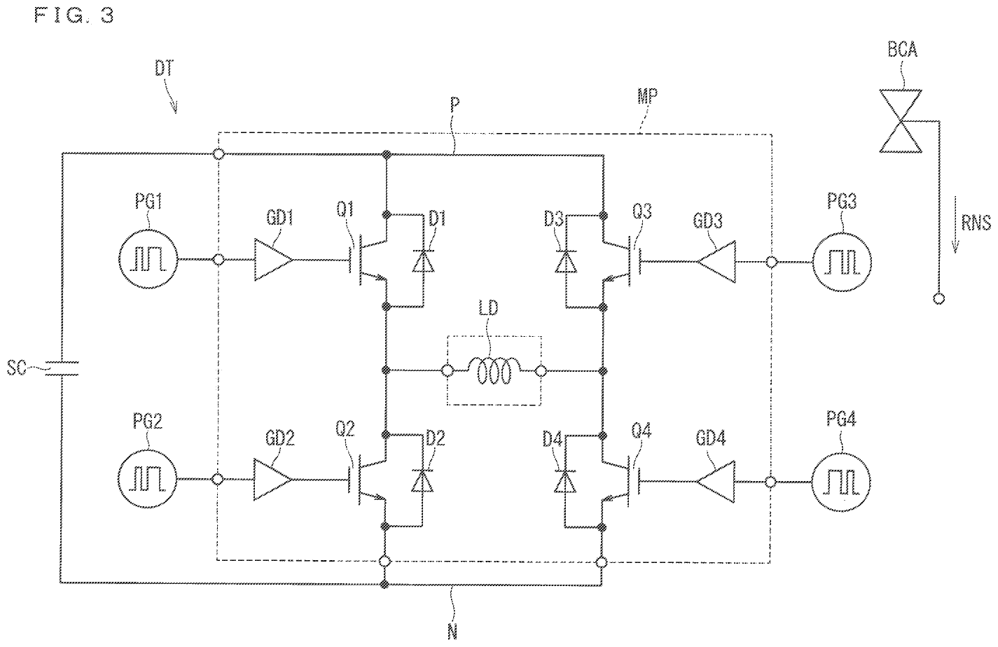

(3) FIG. 3 illustrates a circuit in which a dielectric load LD is connected to an output of a single-phase full bridge circuit as an example of the measured object DT. The single-phase full bridge circuit illustrated in FIG. 3 includes circuit block in which a power transistor Q1 (first transistor) and a power transistor Q2 (second transistor) are connected in series between a power line P (first wiring) connected to a high potential (first potential) terminal of a capacitor SC and a power line N (second wiring) connected to a lower potential (second potential) terminal of the capacitor SC, and a circuit block in which a transistor Q3 and a transistor Q4 are connected in series between the power line P and the power line N. Diodes D1 to D4 are antiparallelly connected to the transistors Q1 to Q4, respectively.

A connection node of the transistor of each circuit block serves as an output node of a single-phase full bridge circuit, and the dielectric load LD is connected between two output nodes. Gate drivers GD1 to GD4 are connected to gates of the transistors Q1 to Q4, respectively, and a pulse signal is inputted from pulse circuits PG1 to PG4 to the gate drivers GD1 to GD4, respectively. Such a single-phase full bridge circuit serves as the measured object DT, thus electromagnetic wave data in case of driving the single-phase full bridge circuit can be obtained.

FIG. 3 illustrates an example of using an insulated gate bipolar transistor (IGBT) as the transistors Q1 to Q4, however, a metal-oxide semiconductor field effect transistor (MOSFET) can also be used.

(4) A transistor to be evaluated is switching-operated by a double pulse test in which a pulse signal is applied twice to a gate of a predetermined transistor, and current flows in the dielectric load LD to the electromagnetic wave generated in the measured object DT is measured by the biconical antenna BCA.

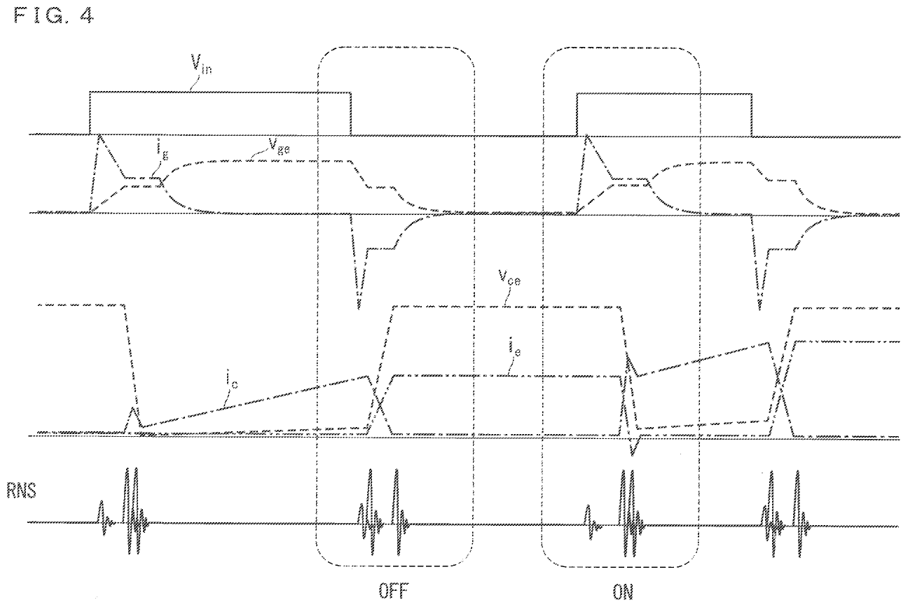

FIG. 4 is a timing chart including the voltage signal RNS from the biconical antenna BCA obtained by applying the pulse signal in the double pulse test. FIG. 4 illustrates an input signal vᵢₙ inputted to the transistor to be evaluated in an uppermost stage, illustrates gate current i_{g} and gate-emitter voltage v_{gc} in a second stage, illustrates a collector-emitter voltage v_{ce}, collector current i_{c}, and emitter current iₑ in a third stage, and illustrates the voltage signal RNS outputted from the biconical antenna BCA in accordance with the detected electromagnetic wave in a lowermost stage. The voltage signal RNS is detected at a timing of turning on and turning off the transistor. The example of the double pulse test is described above, however, the number of applications of pulse signal is not limited to two. The number of applications thereof is not limited as long as it is two or more.

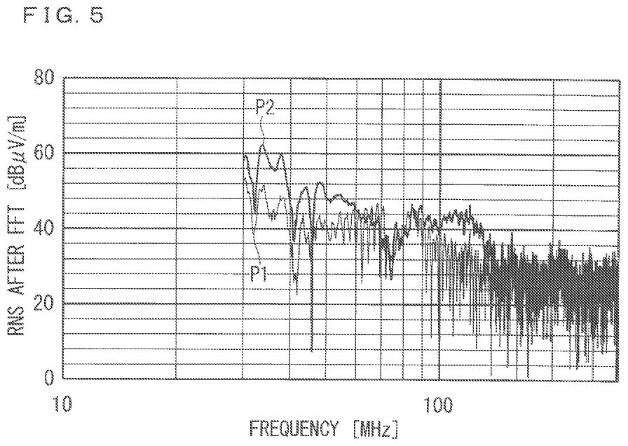

(5) As illustrated in FIG. 4, the electromagnetic wave is generated in each of the turning-on operation and the turning-off operation of the transistor, thus the received signal can be separated into the timing of each of the turning on and the turning off by performing fast Fourier transformation (FFT) on the receiving signal, and a frequency response depending on current is obtained. FIG. 5 illustrates a profile P1 of electromagnetic wave strength at the time of turning on and a profile P2 at the time of turning off obtained by performing Fourier transformation on the voltage signal RNS. In FIG. 5, a lateral axis indicates frequency [MHz], and a vertical axis indicates the voltage signal RNS [dBμV/m] after FFT.

(6) The profile data at the time of turning on and the profile data at the time of turning off illustrated in FIG. 5 are obtained for each load current while changing the load current flowing in the dielectric load LD. That is to say, considering an operation of a motor, the current flows in the motor within a range from 0 A to maximum current flowing in the motor, thus the electromagnetic wave (radiation noise) is generated in the switching operation of the transistor in each period in which the current is within a range from 0 A to the maximum current, and a peak value of the electromagnetic wave is expressed as data in which the detected electromagnetic wave data is stored (superposed). Such electromagnetic wave data is obtained, thus more practical electromagnetic wave data can be stored as the previous data.

For example, when the current flows in the motor within a range from 0 A to maximum current 10 A, a carrier frequency is 10 kHz, and an output frequency is 50 Hz, the transistor is switching-operated 200 times in one cycle of output. In this case, the motor current is divided into 200 pieces from 0 A to 10 A, and increased. The turning-on profile and the turning-off profile in each of the current divided into 200 pieces are superposed to obtain the peak value of the electromagnetic wave.

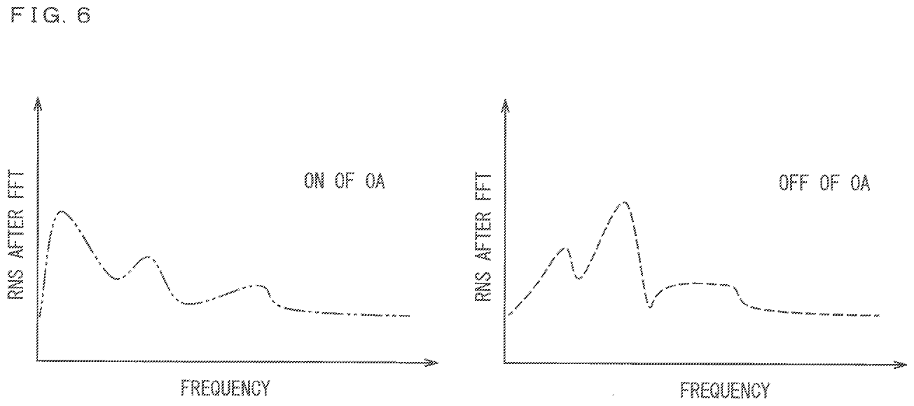

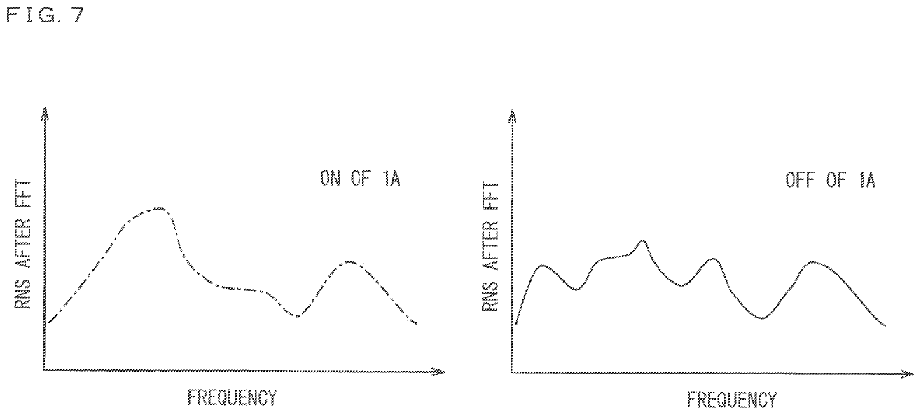

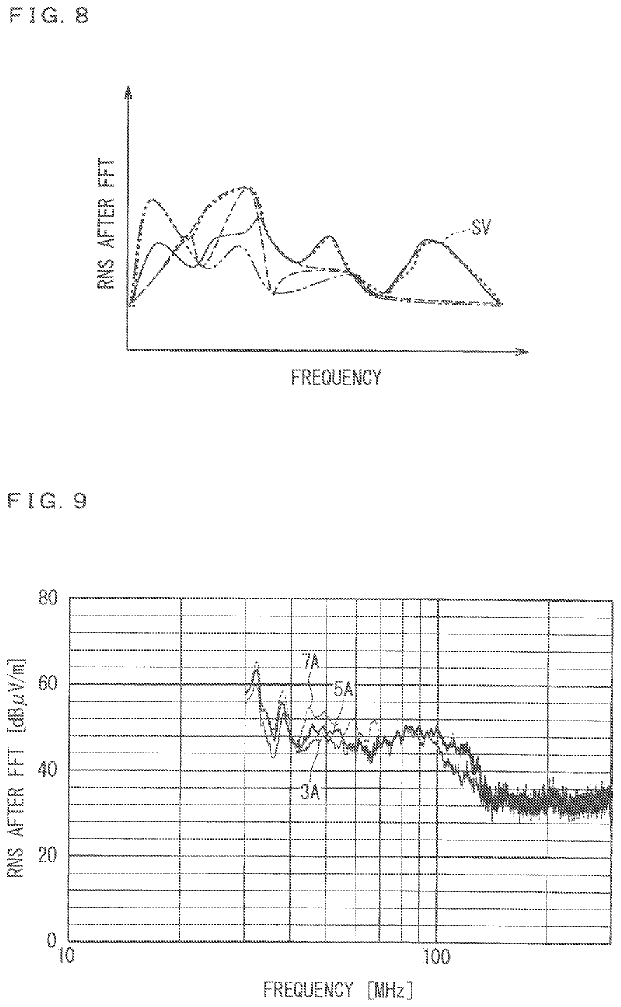

A concept of superposition of the profile is described using FIG. 6 to FIG. 8. FIG. 6 illustrates a profile in a case where the current is 0 A, and the drawing on a left side in FIG. 6 illustrates the turning-on profile, and the drawing on a right side therein illustrates the turning-off profile. FIG. 7 illustrates a profile in a case where the current is 1 A, and the drawing on a left side in FIG. 6 illustrates the turning-on profile, and the drawing on a right side therein illustrates the turning-off profile. FIG. 8 illustrates a profile in which all of the profiles illustrated in FIG. 6 and FIG. 7 are superposed, and the profile illustrated by a thick broken line indicates a peak value SV.

FIG. 9 illustrates a case where the profiles in a case where the current flowing in the dielectric load LD of the measured object DT is set to 3 A, 5 A, and 7 A are superposed as profiles P3, P5, and P7, respectively. In this manner, measurement points of the electromagnetic wave are rougher than the increase of the current divided by the carrier frequency, thus a value between the measurement points is complemented, and the peak value is calculated to obtain the previous data. A linear approximation or a least square method can be used for complementing the value between the pieces of data obtained by measuring the electromagnetic wave. Such processing is performed, thus the measurement points of the electromagnetic wave can be increased, and time consumed for obtaining the electromagnetic wave data can be reduced.

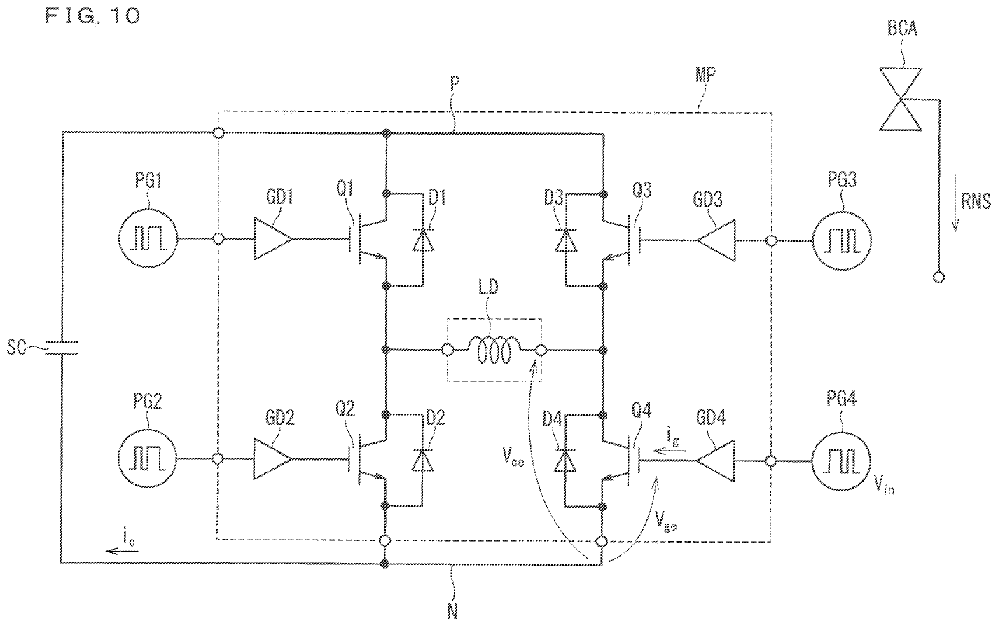

The double pulse test obtaining the profile illustrated in FIG. 9 is described herein. The single-phase full bridge circuit constituting the measured object DT illustrated in FIG. 10 is the same as that illustrated in FIG. 3, however, each type of current and voltage is added. The dielectric load LD is inserted between the output terminals as output parts, thus switching characteristics of the transistors on opposing corners are evaluated while one of the transistors Q1 to Q4 are always in an on state. FIG. 10 illustrates an example of evaluating the switching characteristics of the transistor Q4, and evaluates the switching characteristics of the transistor Q4 while the transistor Q1 is always in an on state.

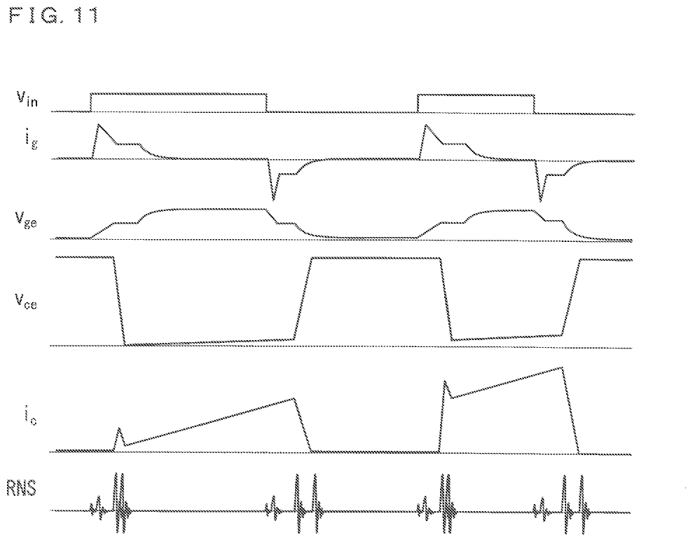

FIG. 11 illustrates the same switching characteristics as that illustrated in FIG. 4 divided for each of current and voltage. FIG. 11 illustrates an input signal vᵢₙ inputted to the transistor to be evaluated in an uppermost stage, illustrates gate current i_{g} in a second stage, illustrates a gate-emitter voltage v_{ge} in a third stage, illustrates collector-emitter voltage v_{ce} in the fourth stage, illustrates collector current i_{c} in a fourth stage, and illustrates the voltage signal RNS in a lowermost stage. Emitter current is omitted.

A motor is driven by the switching operation of an inverter such as the single-phase full bridge circuit illustrated in FIG. 3, and the electromagnetic wave is generated from an apparatus when the motor is driven. In the inverter, alternating current is generally rectified via a diode bridge, and the rectified voltage is unified by a smoothing capacitor, and is inputted to the inverter as DC link voltage. The diode bridge is omitted in the single-phase full bridge circuit illustrated in FIG. 3, and the capacitor SC provided to the input part corresponds to the smoothing capacitor. A part of the power line P and the power line N connected to the capacitor SC exposed to an outer part of a resin package MP is referred to as a DC link wiring (bus wiring).

The electromagnetic wave is generated by the current flowing in a medium, and when a harmonic component thereof is within a range from 30 MHz to 1 GHz, the electromagnetic wave is recognized as a radiation noise. Developers of the present disclosure gain an insight by a test that there are two main factors of the radiation noise that the switching current flowing in the DC link wiring generates the electromagnetic wave by the DC link wiring as an antenna and the harmonic component occurs in the current by a temporal change of earth capacity of the wiring connected to the output terminal of the inverter and the voltage of the terminal part. Then, the developers reach a conclusion that matters which should be considered are a dimension of the DC link wiring and a floating capacity of a parasitic inductance of the inverter and the output terminal of the inverter.

The user US of the semiconductor device using the electromagnetic wave calculation system 10 inputs the type name and the usage condition of the semiconductor device to the electromagnetic wave calculation system 10 in an experimental stage of a product of his/her company, thereby being able to obtain the profile of the radiation noise as the electromagnetic wave data from the electromagnetic wave calculation system 10, thus can grasp the electromagnetic wave generated in the semiconductor device which is scheduled to be used and a surrounding component thereof before the user US measures the electromagnetic wave of a final product.

Examples of the usage condition inputted to the electromagnetic wave calculation system 10 via an interface include a voltage value applied to the semiconductor device, a current value of a current flowing in the semiconductor device, and a length of the bus wiring connected to the semiconductor device from the smoothing capacitor and its inductance. These usage conditions have large influence on occurrence of the radiation noise, thus more actual electromagnetic data can be obtained by inputting these usage conditions to the electromagnetic wave calculation system 10 as parameters.

In addition to these conditions, also applicable as the usage condition are a carrier frequency as the number of switching of the semiconductor device, a dead time as an interval period of the pulse signal inputted to the semiconductor device, and an output frequency of the semiconductor device. Highly accurate electromagnetic data can be obtained by inputting these usage conditions to the electromagnetic wave calculation system 10 as parameters.

Described next is a method of improving accuracy of previous data to improve accuracy of electromagnetic wave data outputted from the electromagnetic wave simulator 1 of the electromagnetic wave calculation system 10 (FIG. 1).

### <Method 1>

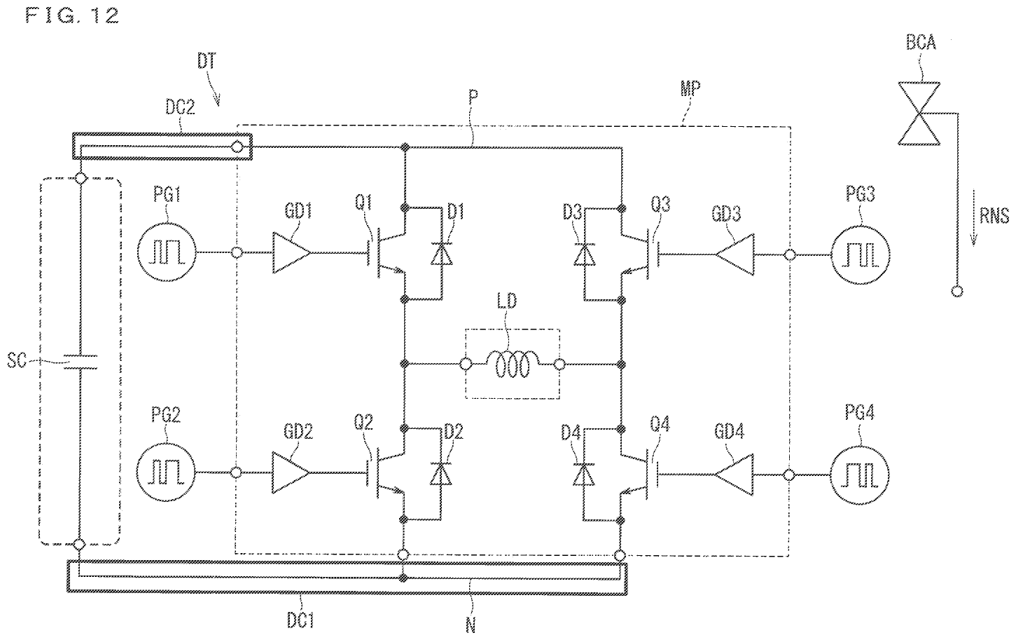

FIG. 12 is a diagram of a region of the bus wiring in the single-phase full bridge circuit of the measured object DT illustrated in FIG. 3 surrounded by a frame, and illustrates a wiring on a low potential side as a bus wiring DC1 and a wiring on a high potential side as a bus wiring DC2.

A length of each of the bus wirings are set to be smaller than one wavelength of an upper limit frequency in a range of a frequency of the radiation noise to be measured. That is to say, the electromagnetic wave occurs by the current flowing in the bus wiring, and the electromagnetic wave is recognized as the radiation noised when the harmonic component thereof is within a range from 30 MH to 1 GHz, thus a frequency range of the radiation noise to be measured is within a range from 30 MHz to 1 GHz. Herein, one wavelength of the frequency with 1 GHz is 300 mm. Accordingly, when the length of the bus wiring is set so that the length of each of the bus wirings DC1 and DC2 is smaller than 300 mm, a resonance phenomenon in which the bus wiring serves as an antenna and strength of the radiation noise with the frequency of 1 GHz fluctuates can be suppressed, thus a stable measurement result can be obtained.

Herein, in FIG. 12, the bus wiring DC1 is longer than the bus wiring DC2 by reason that FIG. 12 illustrates an example of a commercialized semiconductor module. Accordingly, in the semiconductor module, the length of the bus wiring DC1 is reduced in the manner similar to the bus wiring DC2 in some cases, thus the length of the bus wiring DC2 and the length of the bus wiring DC1 may be reversed in some cases. In any case, the bus wiring has a length smaller than one wavelength in the upper limit frequency within the range of the frequency of the radiation noise to be measured, thus the stable measurement result can be obtained.

### <Method 2>

In the method 1 described above, the length of each of the bus wirings DC1 and DC2 does not exceed the length of one wavelength in the upper limit frequency in the range of the frequency of the radiation noise to be measured, however, in a method 2, the length thereof is set to be smaller than ½ wavelength, ¼ wavelength, or ⅛ wavelength.

When the length of the bus wiring is the same as that of one wavelength in the frequency of the radiation noise, resonance occurs at a frequency of ½ wavelength and ¼ wavelength thereof. When the length of the bus wiring is the same as that of ½ wavelength in the frequency of the radiation noise, resonance occurs at a frequency of ¼ wavelength thereof. Accordingly, the length of the bus wiring is smaller than ½ wavelength. ¼ wavelength, or ⅛ wavelength, thus the resonance phenomenon of the electromagnetic wave with the frequency of 1 GHz or less caused by the bus wiring as the antenna is suppressed, and the more stable measurement result can be obtained.

### <Method 3>

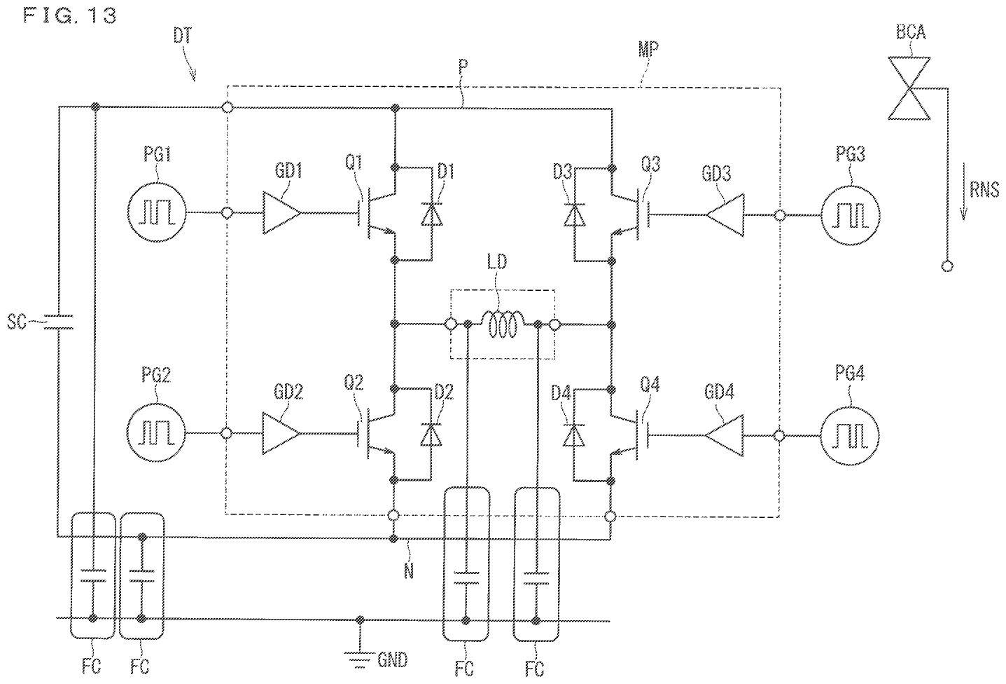

FIG. 13 is a diagram in which a capacitor FC having a fixed capacity is connected between the output terminal and ground (GND) potential and between the bus wiring and the GND potential in the single-phase full bridge circuit of the measured object DT, and a portion to which the capacitor FC is connected is surrounded by a frame.

The output terminal is connected to the dielectric load LD, thus fluctuation of the electromagnetic wave is caused by displacement current due to the temporal change of the voltage at the time of switching of the transistor and the floating capacity of the output terminal and a high frequency component of the displacement current. However, the capacitor FC is connected between the output terminal and the GND potential, thus the electromagnetic wave fluctuates around the electrostatic capacity of the capacitor FC as a central value, and a fluctuation width can be reduced.

The GND potential for the bus wiring fluctuates, the displacement current occurs in combination with the earth capacity, and fluctuation of the electromagnetic wave occurs. However, the capacitor FC is connected between the bus wiring and the GND potential, thus the electromagnetic wave fluctuates around the electrostatic capacity of the capacitor FC as a central value, and a fluctuation width can be reduced.

### <Method 4>

Described in the method 3 described above is a method of connecting the capacitor FC between the output terminal and the GND potential and between the bus wiring and the GND potential, however, the capacitor FC includes parasitic inductance. Thus, there is a resonance point by the electrostatic capacity of the capacitor FC and the parasitic inductance. In a method 4, the electrostatic capacity of the capacitor FC is set so that the resonance point is smaller than 30 MHz or equal to or larger than 1 GHz.

For example, when the parasitic inductance of the capacitor is Ls, and the capacity of the capacitor is C, a resonance frequency f is calculated by f=1/(2π√(Ls·C)). For example, when Ls=2 nH and C=10 pF are satisfied, the resonance frequency exceeds 1 GHz, and when Ls=30 nH and C=1 nF are satisfied, the resonance frequency falls below 30 MHz.

Accordingly, occurrence of the radiation noise having the frequency smaller than 30 HMz and the noise having the frequency of 1 GHz or more can be suppressed. That is to say, the frequency of the radiation noise to be measured is within the range from 30 MHz to 1 GHz in accordance with a standard of the semiconductor device to be measured. Influence on a measurement environment caused by occurrence of the radiation noise having a non-standard frequency can be reduced, and measurement accuracy of the radiation noise can be increased.

An LCR meter can be used for measuring the parasitic inductance of the capacitor. When a surface-mounting (SMD) type capacitor is attached, the parasitic inductance of the wiring connected to the capacitor also needs to be measured, thus measurement by a time domain reflectometry method (TDR method) is also performed.

### <Method 5>

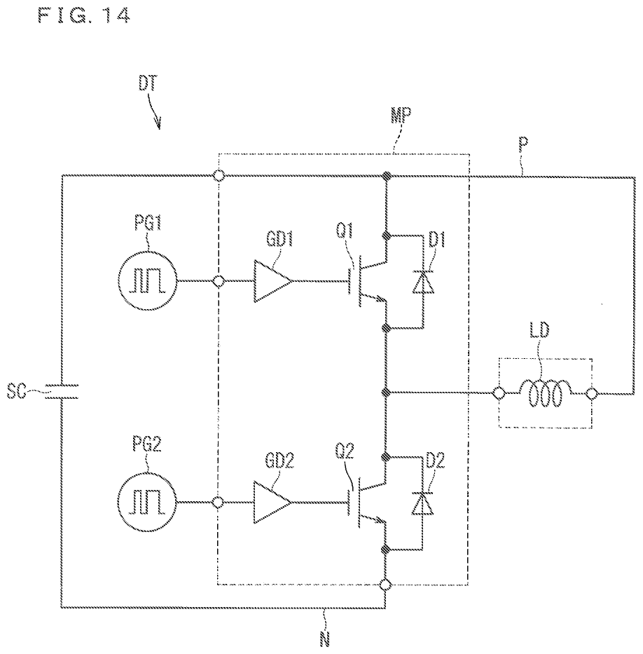

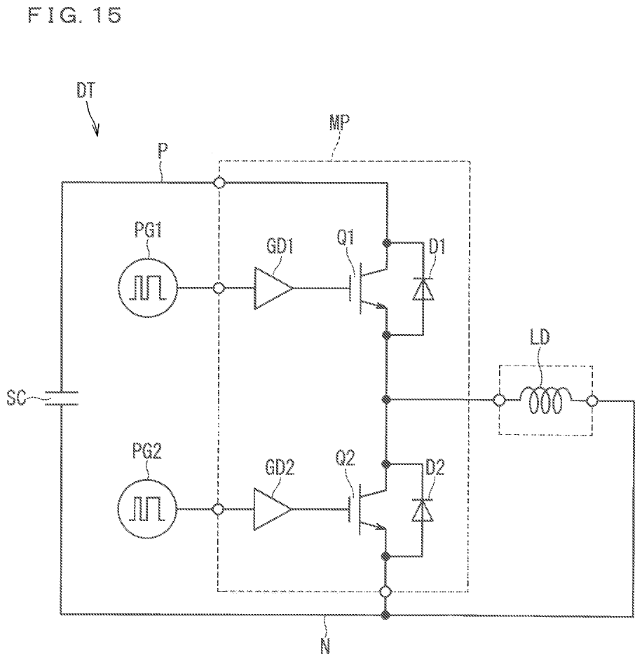

FIG. 14 and FIG. 15 illustrate a circuit in which the dielectric load LD is connected to the output of a half bridge circuit as an example of the measured object DT. The half bridge circuit illustrated in FIG. 14 and FIG. 15 includes the transistor Q1 and the transistor Q2 connected in series between the power line P connected to a high potential terminal of the capacitor SC and the power line N connected to a low potential terminal. The diodes D1 to D2 are antiparallelly connected to the transistors Q1 to Q2, respectively. The connection node of the transistor Q1 and the transistor Q2 serves as the output node of the half bridge circuit. The dielectric load LD is connected between the output node and the collector of the transistor Q1 in FIG. 14, and the dielectric load LD is connected between the output node and the emitter of the transistor Q2 in FIG. 15. In addition, the same sign is assigned to the same configuration as that of the single-phase full bridge circuit illustrated in FIG. 3, and the repetitive description is omitted.

The half bridge circuit illustrate in FIG. 14 and FIG. 15 is an evaluation circuit of a half bridge circuit conforming to a standard of International Electrotechnical Commission (IEC). FIG. 14 is an evaluation circuit in a case of evaluating the transistor Q2, and FIG. 15 is an evaluation circuit in a case of evaluating the transistor Q1.

The measured object DT is made up of these circuits, thus the electromagnetic wave can be measured without being influenced by the other phase.

### <Method 6>

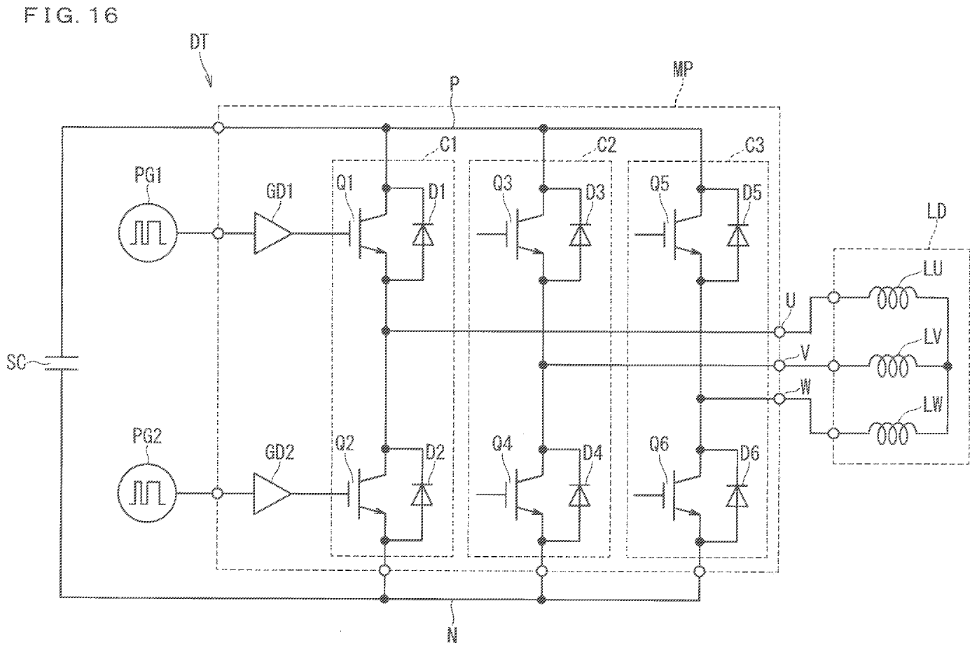

FIG. 16 illustrates a circuit in which the three-phase dielectric load LD is connected to the output of the three-phase full bridge circuit as an example of the measured object DT. The three-phase full bridge circuit illustrated in FIG. 16 includes a circuit block C1 in which the transistor Q1 and the transistor Q2 are connected in series between the power line P connected to the high potential terminal of the capacitor SC and the power line N connected to the lower potential terminal of the capacitor SC, a circuit block C2 in which the transistor Q3 and the transistor Q4 are connected in series between the power line P and the power line N, and a circuit block C3 in which a transistor Q5 and the transistor Q6 are connected in series between the power line P and the power line N. Diodes D1 to D6 are antiparallelly connected to the transistors Q1 to Q6, respectively.

The connection node of the transistor of the circuit block serves as the output node of the three-phase full bridge circuit, the connection node of the circuit block C1 serves as a U-phase output node, the connection node of the circuit block C2 serves as a V-phase output node, and the connection node of the circuit block C3 serves as a W-phase output node. One end of a dielectric load LU is connected to the U-phase output node, one end of the dielectric load LV is connected to the V-phase output node, one end of a dielectric load LW is connected to the W-phase output node, and the other end of each dielectric load is connected in common. Gate drivers are connected to gates of the transistors Q1 to Q6, respectively, pulse circuits are connected to the gate drivers, respectively, and the pulse signal is inputted. Only the gate drivers GD1 and GD2 and the pulse circuits PG1 and PG2 are illustrated for a descriptive purpose.

The three-phase dielectric load LD is connected to simulate a motor load and a three-phase transformer, thus when the measured object DT has the circuit illustrated in FIG. 15, the electromagnetic wave simulating an operation closer to the load of the motor and the power network can be measured.

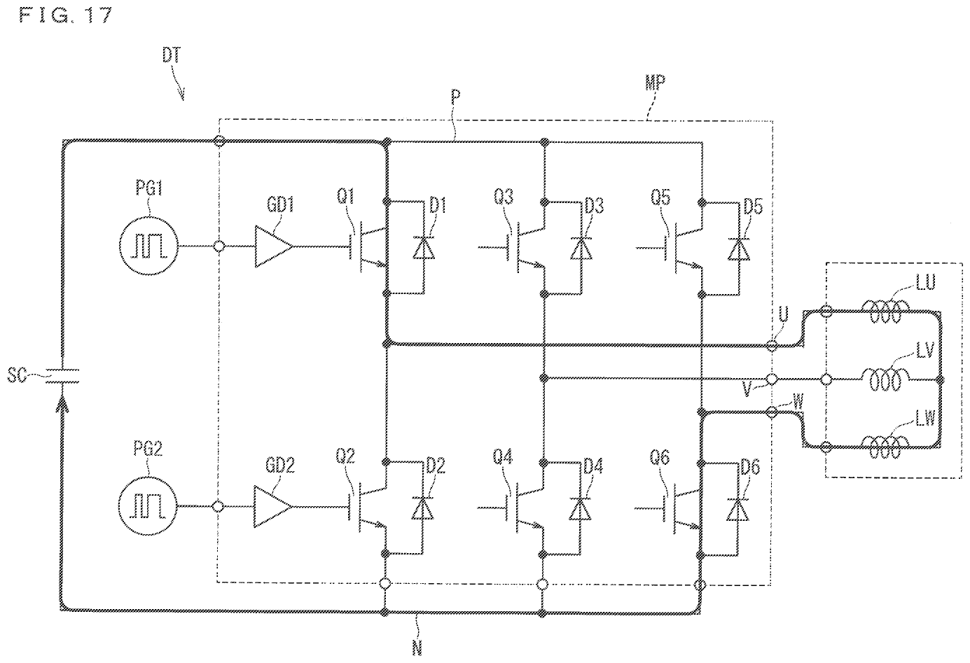

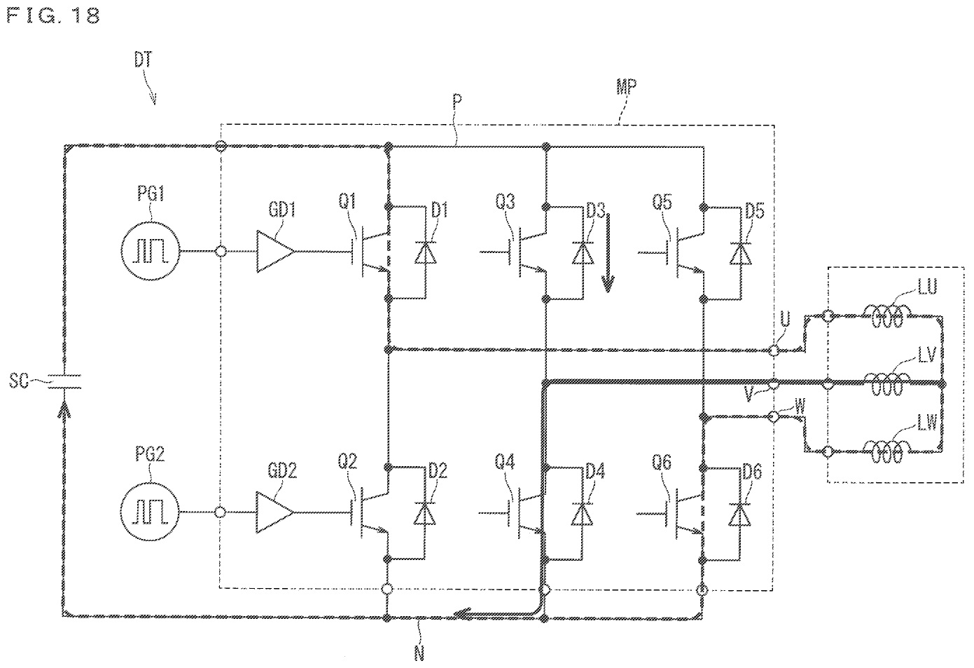

FIG. 17 and FIG. 18 illustrate a flow of current in a case where the three-phase full bridge circuit is operated, and FIG. 17 illustrates current in a case where the transistors Q1 and Q6 are electrically connected by an arrow. The current flows to the transistor Q6 from the transistor Q1 via the dielectric loads LU and LW.

FIG. 18 illustrates a flow of the current in a case where the current suddenly flows in the transistor Q4 from this state. The current flowing in the transistor Q6 decreases by sudden division of current in which the current flows also via the dielectric load LV by sudden electrical conduction of the transistor Q4. Moreover, the diode D3 connected to the transistor Q3 is recovery-operated, and the current flowing in the transistor Q4 rapidly increases.

In this manner, the measured object DT includes the circuit in which the three-phase dielectric load LD is connected to the output of the three-phase full bridge circuit, thus the electromagnetic wave according to the change of current flowing in the transistor Q4 can be measured together with the recovery operation of the diode D3. The three-phase full bridge circuit in FIG. 16 can simulate a more complex operation, which is not limited to the operation described above, by the combination of the operations of the transistors Q1 to Q6 and the diode D1 to D6

### <Method 7>

The measured object DT in FIG. 16 described in the method 5 described above is the three-phase full bridge circuit, and is a so-called 6-in-1 module in which six transistors are housed in one resin package MP, however, the measured object DT is not limited thereto. For example, the single-phase full bridge circuit illustrated in FIG. 3 is a 4-in-1 module in which four transistors are housed in one resin package MP, and the half-bridge circuit illustrated in FIG. 14 and FIG. 15 is a 2-in-1 module in which two transistors are housed in one resin package MP.

In addition, a 1-in-1 module in which one transistor is housed in one resin package MP can be the measured object DT. When two 1-in-1 modules are connected in series, the half-bridge circuit can be made, when two 1-in-1 modules are parallelly connected, the single-phase full bridge circuit can be made, and when three 1-in-1 modules are parallelly connected, the three-phase full bridge circuit can be made. The 1-in-1 module is referred to “discrete (discrete semiconductor)”. For example, when the half bridge circuit is made by the 1-in-1 module, only a defective module needs to be replaced when one module breaks down, thus the 1-in-1 module is economic.

In this manner, the electromagnetic wave is measured using the half-bridge circuit, the single-phase full bridge circuit, and the three-phase full bridge circuit made using the discrete as the measured object DT, thus the previous data corresponding to the discrete can be obtained.

Examples of the 4-in-1 module is not limited to the single-phase full bridge circuit illustrated in FIG. 3, but can include a module used in a three-level inverter.

### <Method 8>

In the method of measuring the electromagnetic wave described using FIG. 2, the distance DL from the measured object DT to the biconical antenna BCA is 3 m to 10 m in the radio wave darkroom BR. It is the distance in a case of conforming CISPR standard, and the electromagnetic wave data conforming to the CISPR standard can be obtained.

However, the distance thereof is not limited thereto. For example, when an evaluation in an outdoor open are test site (OATS) is considered, a distance to the antenna is approximately 30 m in maximum. The measurement is performed with the distance of 1 m±0.01 m from the antenna to a harness in a vehicle environment, and a measurement distance of the electromagnetic wave may be 0.9 m to 30 m.

This configuration does not conform to the CISPR standard, however, more realistic measurement result of the electromagnetic wave can be obtained.

Strength of the electromagnetic wave can be log-linearly converted by a distance when the distance is 3 m in minimum based on the measurement result of the distance of 10 m conforming to the CISPR standard.

For example, the measurement result (strength Z) with the distance 10 m can be converted with the following expression (1) using the measurement result (strength Y) with the distance 3 m.

$$\begin{matrix}[ Expression 1 ] & \\ Z = Y + 20 \cdot log 10 ( 3 ) - 20 \cdot log 10 ( 10 ) & ( 1 )\end{matrix}$$

Thus, the strength (X) with an optional distance (A meter) equal to or larger than 3 m can be converted with the following expression (2).

$$\begin{matrix}[ Expression 2 ] & \\ X = Y + 20 \cdot log 10 ( 3 ) - 20 \cdot log 10 ( A ) & ( 2 )\end{matrix}$$

### <Method 9>

When the electromagnetic wave occurring at the time of turning on and turning off the transistor obtained in the double pulse test is compared, the measured voltage signal RNS is cut with a predetermined temporal width and compared. The temporal width to be cut can be 1/120 kHz (approximately 8.33 μs) and 1/100 kHz (10 μs) based on a resolution bandwidth (RBW) in accordance with the CISPR standard and united states military standard (MIL standard). Accordingly, the electromagnetic wave data conforming to the CISPR standard and the MIL standard can be obtained.

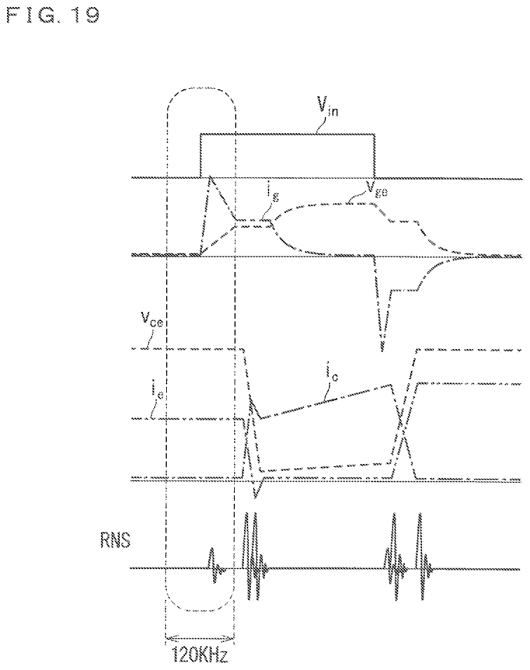

FIG. 19 illustrates one example thereof. FIG. 19 illustrates the electromagnetic wave occurring at the time of turning on in the measurement result of the electromagnetic wave in the double pulse test illustrated in FIG. 4, and a framed region assigned with ON falls under a region of the predetermined temporal width. This example indicates a case of cutting with 1/120 kHz (approximately 8.33 μs).

The temporal width to be cut is not limited to the CISPR standard or the MIL standard, but an optional temporal width is also applicable. Although such a configuration does not conform to the CISPR standard and the MIL standard, it is possible to measure and compare the strength by cutting a specific range, such as only a time of a gate driving or an operation range of a power part, by cutting the signal with an optional temporal width.

### <Method 10>

When Fourier transformation is performed on the electromagnetic wave occurring at the time of turning or turning off the transistor obtained in the double pulse test as illustrated in FIG. 4, the same analysis result as a general spectrum analyzer can be obtained by using Gaussian window function. Kaiser window function can also be used in place of Gaussian window function.

Gaussian window function is expressed by the following expression (3), and Kaiser window function is expressed by the following expression (4). In the expression (4), 10 indicates zero-order Wessel function.

$$\begin{matrix}[ Expression 3 ] & \\ ω ( x ) = exp ( - \frac{{x}^{2}}{{σ}^{2}} ) & ( 3 )\end{matrix}$$

$$\begin{matrix}[ Expression 3 ] & \\ ω ( x ) = \frac{{I}_{0} \{ πα \sqrt{1 - {( 2 x - 1 )}^{2}} \}}{{I}_{0} ( πα )} , if 0 \leq k \leq 1 & ( 4 )\end{matrix}$$

Lower strength can be analyzed by using Kaiser window function. More accurate analysis result can be obtained by using Kaiser window function than by using the other window function.

### <Method 11>

As illustrated in FIG. 5, the profile obtained by performing Fourier transformation on the measured voltage signal RNS is the data obtained by applying the specific current value and voltage value to the measured object DT in the double pulse test on the measured object DT (FIG. 2), and is discrete data. Thus, the data is assumed to be used with a current value and a voltage value different from the specific current value and voltage value in applying the data to drive the motor, for example. In such a case, the complement by a linear approximation or a least square method is performed using existing data to obtain the profile.

For example, in a case where the current in the motor flows up to 2.5 A, when the profile obtained by the result of the double pulse test in the darkroom includes only a case where the current is 0 A, 1 A, 2 A, and 3 A, there is no profile including a case where the conduction current of the motor has a maximum value of 2.5 A, thus data in a case of 2.5 A is made by converting the profiles of 2 A and 3 A, and the other data is superposed with the data to determine a peak value.

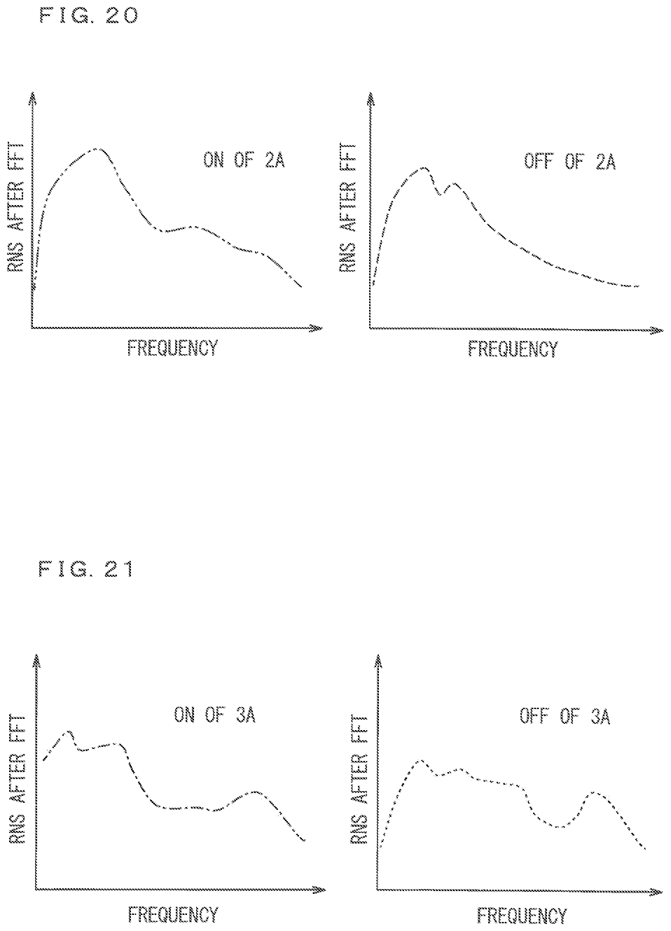

A method of obtaining the profile by the complement is described using FIG. 20 to FIG. 22. FIG. 20 illustrates a profile in a case where the current is 2 A, and the drawing on a left side in FIG. 20 illustrates the turning-on profile, and the drawing on a right side therein illustrates the turning-off profile. FIG. 21 illustrates a profile in a case where the current is 3 A, and the drawing on a left side in FIG. 21 illustrates the turning-on profile, and the drawing on a right side therein illustrates the turning-off profile.

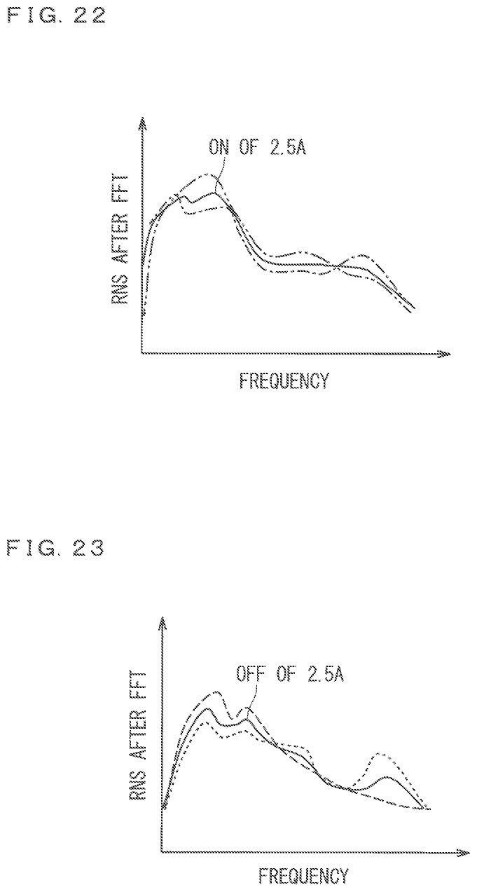

FIG. 22 illustrates the turning-on profile in a case of the current 2.5 A created by complement from the turning-on profile on the left side in FIG. 20 and the turning-on profile on the left side in FIG. 21. FIG. 23 illustrates the turning-off profile in a case of the current 2.5 A created by complement from the turning-off profile on the right side in FIG. 20 and the turning-off profile on the right side in FIG. 21. All of the profiles illustrated in FIG. 20 to FIG. 22 are superposed to obtain the profile of the peak value with the current 2.5 A.

The complement is performed using the measured existing data, thus more practical electromagnetic wave data can be calculated.

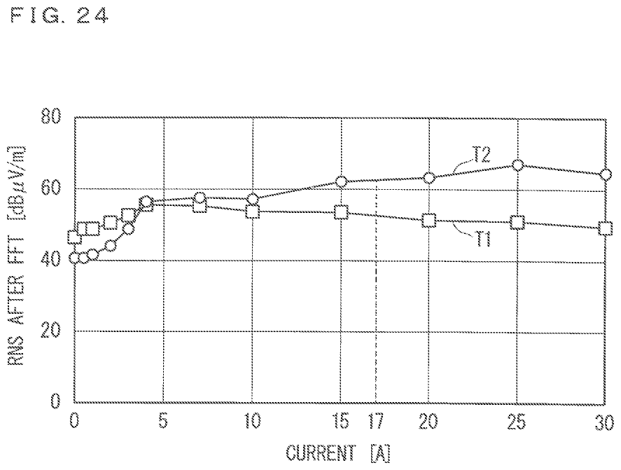

FIG. 24 is a diagram explaining a complement by a linear approximation as an example of complement of the data. FIG. 24 illustrates current [A] flowing in the measured object DT in a lateral axis, illustrates a peak value of the voltage signal RNS [dBμV/m] after FFT in a vertical axis, and illustrates a characteristic T1 of the peak value (on peak) at the time of turning on and a characteristic T2 of the peak value (off peak) at the time of turning off.

In FIG. 24, the characteristics T1 and T2 are data in which the current is measured at interval of 5 A, and data points are connected by the linear approximation. Thus, the electromagnetic wave strength with the current 17 A, for example, can be obtained by a straight line connecting data points of 15 A and 20 A. In this manner, the complement can be performed using the existing data even when the measurement data is not obtained, thus time for measuring the data can be reduced.

According to the present disclosure, the embodiments can be appropriately varied or omitted within the scope of the disclosure.

While the invention has been shown and described in detail, the foregoing description is in all aspects illustrative and not restrictive. It is therefore understood that numerous modifications and variations can be devised without departing from the scope of the invention.

What is claimed is:

1. An electromagnetic wave calculation system calculating an electromagnetic wave generated in a semiconductor device, comprising:
an electromagnetic wave simulator; and
a previous data memory, wherein
the electromagnetic wave simulator and the previous data memory have communication with each other via network,
the previous data memory records electromagnetic wave data of the semiconductor device corresponding to a type name of the semiconductor and a usage condition of the semiconductor device as previous data, and
when the type name and the usage condition of the semiconductor device are inputted, the electromagnetic wave simulator has communication with the previous data memory, and outputs the electromagnetic wave data under the usage condition of the semiconductor device.

2. The electromagnetic wave calculation system according to claim 1, wherein
the electromagnetic wave simulator is built up on a computer connected to the network.

3. The electromagnetic wave calculation system according to claim 1, wherein
the electromagnetic wave simulator is accessed from a homepage of a company of a user of the semiconductor device.

4. The electromagnetic wave calculation system according to claim 1, wherein
the semiconductor device includes a transistor, and
stored in the previous data memory is profile data of electromagnetic wave strength at a time switching-operating the transistor under the usage condition for each the type name of the semiconductor device.

5. The electromagnetic wave calculation system according to claim 4, wherein
the usage condition includes a voltage value applied to the semiconductor device, a current value of current flowing in the semiconductor device, and a carrier frequency as a total number of switching of the transistor.

6. The electromagnetic wave calculation system according to claim 4, wherein
the usage condition includes a length and inductance of a bus wiring connected to the transistor from a smoothing capacitor connected to the semiconductor device.

7. The electromagnetic wave calculation system according to claim 4, wherein
the usage condition includes a dead time as an interval period between pulses of a pulse signal for turning on and off the transistor.

8. The electromagnetic wave calculation system according to claim 4, wherein
the usage condition includes an output frequency of the semiconductor device.

9. A method of obtaining the previous data recorded in the previous data memory of the electromagnetic wave calculation system according to claim 4, wherein
a measured object including the semiconductor device is prepared, and
the previous data
detects the electromagnetic wave generated by switching-operating the transistor constituting the measured object under the usage condition with an antenna to be a voltage signal, and
is profile data of a voltage signal after Fourier transformation in which the voltage signal is cut with a predetermined temporal width and is partially Fourier transformed to convert into frequency.

10. The method of obtaining the previous data according to claim 9, wherein
the measured object includes a dielectric load connected to an output node of the semiconductor device,
the profile data includes plural pieces of profile data for each load current obtained by changing the load current flowing in the dielectric load, and
the previous data is data of a peak value of a profile calculated by superposing the plural pieces of profile data.

11. The method of obtaining the previous data according to claim 10, wherein
the measured object includes a smoothing capacitor for rectification connected to an input node of the semiconductor device, and
the previous data is the profile data of the voltage signal after the Fourier transformation calculated based on the voltage signal in which a length of a bus wiring connected to the transistor from the capacitor is smaller than a length of one wavelength in an upper limit frequency in a frequency range of the electromagnetic wave to be measured.

12. The method of obtaining the previous data according to claim 11, wherein
the length of the bus wiring is smaller than ½ wavelength or ¼ wavelength in the upper limit frequency.

13. The method of obtaining the previous data according to claim 9, wherein
the measured object includes:
a dielectric load connected to an output node of the semiconductor device; and
a smoothing capacitor connected to an input node of the semiconductor device, wherein
the previous data is the profile data of the voltage signal after the Fourier transformation calculated based on the voltage signal measured by connecting a capacitor having a fixed capacity between an output terminal connected to the dielectric load and ground potential and/or between a bus wiring connected to the transistor from the smoothing capacitor and the ground potential.

14. The method of obtaining the previous data according to claim 13, wherein
the capacitor includes an electrostatic capacitance of the capacitor and a parasitic inductance, and
the electrostatic capacitance is set so that a resonance point by the electrostatic capacitance and the parasitic inductance is smaller than 30 MHz or equal to or larger than 1 GHz to measure the voltage signal.

15. The method of obtaining the previous data according to claim 9, wherein
the semiconductor device includes a half-bridge circuit made up of a first transistor and a second transistor as the transistor connected in series between a first wiring applying first potential and a second wiring applying second potential lower than the first potential, and
the previous data is
the voltage signal measured by connecting a dielectric load between an output terminal of the half-bridge circuit and the first wiring or
the profile data of the voltage signal after the Fourie transformation calculated based on the voltage signal measured by connecting the dielectric load between the output terminal and the second wiring of the half-bridge circuit.

16. The method of obtaining the previous data according to claim 9, wherein
the semiconductor device includes a three-phase full bridge circuit,
the measured object includes a three-phase dielectric load connected between output terminals of the three-phase full bridge circuit, and
the previous data is the profile data of the voltage signal after the Fourie transformation calculated based on the voltage signal measured by connecting the three-phase dielectric load.

17. The method of obtaining the previous data according to claim 9, wherein
the semiconductor device includes
a circuit including at least the transistor and a diode antiparallelly connected to the transistor, and
the previous data is the profile data of the voltage signal after the Fourie transformation calculated based on the voltage signal measured by switching-operating the circuit.

18. The method of obtaining the previous data according to claim 9, wherein
the previous data is the profile data of the voltage signal after the Fourie transformation calculated based on the voltage signal measured by setting a distance (DL) from the measured object to the antenna to 3 m to 10 m.

19. The method of obtaining the previous data according to claim 18, wherein
when the distance from the measured object to the antenna is equal to or larger than 3 m, the electromagnetic strength measured with the distance of 3 m is Y, and
when the electromagnetic strength in a case where an optional distance is A is X, the X is converted by an expression (1), and
the previous data includes the profile data of the electromagnetic strength converted by the expression (1).
$$Z = Y + 20 \cdot log 10 ( 3 ) - 20 \cdot log 10 ( A ) \qquad ( 1 )$$

20. The method of obtaining the previous data according to claim 9, wherein
the predetermined temporal width with which the voltage signal is cut is set to 1/120 kHz or 1/100 kHz based on a resolution bandwidth according to CISPR standard and MIL standard.

21. The method of obtaining the previous data according to claim 9, wherein
the predetermined temporal width with which the voltage signal is cut is set to an optional temporal width other than 1/120 kHz and 1/100 kHz based on a resolution bandwidth according to CISPR standard and MIL standard.

22. The method of obtaining the previous data according to claim 9, wherein
Gaussian window function of an expression (2) is used for the Fourier transformation.
$$ω ( x ) = exp ( - \frac{{x}^{2}}{{σ}^{2}} ) \qquad ( 2 )$$

23. The method of obtaining the previous data according to claim 9, wherein
Kaiser window function of an expression (3) is used for the Fourier transformation.
$$ω ( x ) = \frac{{I}_{0} \{ πα \sqrt{1 - {( 2 x - 1 )}^{2}} \}}{{I}_{0} ( πα )} , if 0 \leq k \leq 1 \qquad ( 3 )$$
